(19) United States
(12) Patent Application Publication
(10) Pub. No.: US 2011/0089791 A1
(43) Pub. Date: Apr. 21, 2011

(54) ELECTRONIC DEVICE HAVING BAMBOO APPEARANCE AND BAMBOO FILM STRUCTURE THEREOF

(76) Inventors: Tsung-Tang Shih, Taipei (TW); Jhung-Ren Huang, Taipei (TW); Mu-Tsai Chang, Taipei (TW)

(21) Appl. No.: 12/906,749

(22) Filed: Oct. 18, 2010

(30) Foreign Application Priority Data
Oct. 19, 2009 (TW) 098135215

(51) Int. Cl. B32B 21/08; H05K 5/02; B32B 21/04; B32B 27/06; B32B 25/04; B65D 85/00

(52) U.S. Cl. 312/223.1; 428/537.1; 428/480; 428/496; 206/701

(57) ABSTRACT

A bamboo film structure includes an adhesive layer made of glue based on PSB. A bamboo laminate sheet is stuck to a film layer directly by the adhesive layer, instead of being stuck to the nonwoven, fiber fabric and baking and polished in the conventional technique. The conventional bamboo laminate is difficult to process due to hardening, but the bamboo film structure in the invention overcomes the disadvantage and can be mass produced by the processes such as an in-mold decoration (IMD) and is attached to an electronic product to reduce working procedures and greatly decrease labor hour.

### BACKGROUND OF THE INVENTION

1. Field of the Invention

The invention relates to a bamboo film structure and, more particularly, to a bamboo film structure in which a bamboo laminate sheet is directly attached to a film layer.

2. Description of the Related Art

In recent years, it is fashion to use natural materials in electronic devices to replace the cold and hard plastic or metal materials of the conventional technology. Among the natural materials, bamboo and wood are particularly noticed. In the conventional bamboo manufacturing process, after the bamboo laminate is slit, nonwoven or fiber fabric is attached to the bamboo laminate at the back. After three-times coating, three-times baking and three-times polishing, the surface of the bamboo laminate is flatted and the color is adjusted. Finally, protective paint is coated on the bamboo laminate sheet, and the bamboo laminate sheet may be stuck to the outer surface of the electronic product.

However, after the three-times coating and three-times baking processes, the bamboo laminate may be harden to be a bamboo sheet, the subsequent manufacturing process is thus limited, and it only may be attached to the electronic product in a sticking way. In addition, since the bamboo laminate is harden, the permitted tolerance between the bamboo laminate and the electronic product is rather small, and therefore the manufacturing cost increases. Moreover, the back of the bamboo laminate includes nonwoven and fiber fabric to prevent the fiber of the bamboo laminate from peeling off. However, the nonwoven and fiber fabric can not tolerate high temperature, and they easily shrink. Therefore, the injecting mode process for manufacturing the electronic product can not be used. In practical usage, the bamboo laminate is adhered to the case of the electronic product one after another by manual labor, which costs the manufacturing time.

Moreover, the process of sticking the nonwoven, the fiber fabric to the bamboo laminate and the processes of three-times coating, three-times baking and three-times polishing are rather complex, and the manufacturing time is prolonged. Since the error is accumulated in every procedure, the yield of the bamboo laminate can not be improved.

### BRIEF SUMMARY OF THE INVENTION

The bamboo film structure in the invention includes a bamboo laminate sheet, an adhesive layer and a film layer. The adhesive layer is made of glue based on the PSB, and it is coated on one side of the bamboo laminate sheet and permeates through the bamboo fiber to improve the sticking effect to make it firmly attached to the film layer. The film layer is made of films such as polydiethylene terephthalate (PET), which is thin and heat-resistant. Therefore, the whole bamboo film structure can resist high temperature, and it is hard to deform or shrink. The film structure is formed due to the reduction of the whole thickness, and the modes for the subsequent manufacture may be variable. Moreover, an in-mold decoration (IMD) technique also may be used to the bamboo film structure to improve the capacity of electronic products with bamboo laminates.

Therefore, the bamboo film structure in the invention does not need to stick the bamboo laminate to the nonwoven and fiber fabric, and it also does not need the three-times coating process, three-times baking process and three-times polishing process. The bamboo film structure in the invention is directly attached to the film layer. This not only reduces the manufacturing time and simplifies process, but also makes the sequence manufacturing modes variable, which is benefit for mass production.

These and other features, aspects and advantages of the present invention will become better understood with regard to the following description, appended claims, and accompanying drawings.

### BRIEF DESCRIPTION OF THE DRAWINGS

FIG. 1A is a schematic diagram showing the bamboo film structure in an embodiment of the invention.

FIG. 1B is a schematic diagram showing part of the enlarged bamboo film structure in an embodiment of the invention.

FIG. 2 is a schematic diagram showing the bamboo film structure in the embodiment of the invention.

FIG. 3A and FIG. 3B are schematic diagram showing that the bamboo film structure is used in an in-mold decoration (IMD) technique.

FIG. 4 is a schematic diagram showing that the bamboo film structure is used in another embodiment of the invention.

FIG. 5 is a schematic diagram showing the bamboo film structure in another embodiment of the invention.

FIGS. 6A and 6B are schematic diagrams showing that the bamboo film structure is used in another embodiment to combine with an electronic device of the invention.

FIG. 7 is a schematic diagram showing that the bamboo film structure is used in another embodiment to combine with an laptop computer of the invention.

### DETAILED DESCRIPTION OF THE EMBODIMENTS

Similar to a furniture surface, the conventional bamboo laminate needs to be baked and polished for several times, and the bamboo laminate is hard to be processed due to hardening. Unlike the conventional bamboo laminate, a bamboo film structure is provided in the invention to simplify the manufacturing process, save manufacturing time and facilitate the subsequent manufacturing process and mass production.

FIG. 1A is a schematic diagram showing the bamboo film structure in an embodiment of the invention. The bamboo film structure in the embodiment includes a bamboo laminate sheet 10, an adhesive layer 20 and a film layer 30. The bamboo laminate sheet 10 is usually formed by cutting, slitting, rough plane, carbonization, drying, fine plane, coating glue, pressing into sheet, stewing, combining to be bamboo sheet, drying and planishing, sanding, cutting and other processes by suppliers. Since the processed bamboo is rather thin, and the binding force between the bamboo fibers is weak, the bamboo fiber is easy to break along the direction of fiber growth. Conventionally, the bamboo laminate sheet 10 is attached to the nonwoven and the fiber fabric, but in the embodiment of the invention, an adhesive layer 20 is coated at one side of the bamboo laminate sheet 10 to combine the film layer 30 with the bamboo laminate sheet 10 via the adhesive layer 20.

As shown in FIG. 1B, since the bamboo laminate sheet 10 includes multiple bamboo fibers 11, when the glue is coated, the glue may permeate into the bamboo fiber 11 to reinforce the strength of the bamboo laminate sheet 10 and help the bamboo laminate sheet 10 to be stuck to the film layer 30 firmly. Therefore, the proportion of ingredients in the adhesive layer 20 is important, which needs to make the bamboo laminate sheet 10 stuck to the electronic product to be sequentially processed without changing the characteristic of the bamboo fiber 11. Therefore, the adhesive layer 20 cannot be one of the current glues.

The adhesive layer 20 at least includes rubber solvent, petroleum ether, styrene-butadiene rubber and synthetic resin. The rubber solvent occupies 5%-20% of the adhesive layer. The petroleum ether occupies 8%-30% of the adhesive layer. The styrene-butadiene rubber occupies 5%-20% of the adhesive layer. The synthetic resin occupies 15%-30% of the adhesive layer. In addition, it is preferably to add some filler to adjust the ingredient. After the adjustment, the rubber solvent occupies 10%-12% of the adhesive layer, the petroleum ether occupies 15%-20% of the adhesive layer, the styrene-butadiene rubber occupies 11%-13% of the adhesive layer, the synthetic resin occupies 20%-25% of the adhesive layer, and the filler occupies 1%-2% of the adhesive layer. Furthermore, to facilitate the combination of the bamboo laminate sheet 10 and the film layer 30, the glue may be heat transfer glue based on PSB, which may attach the bamboo laminate sheet 10 to the film layer 30 in a heat transfer mode.

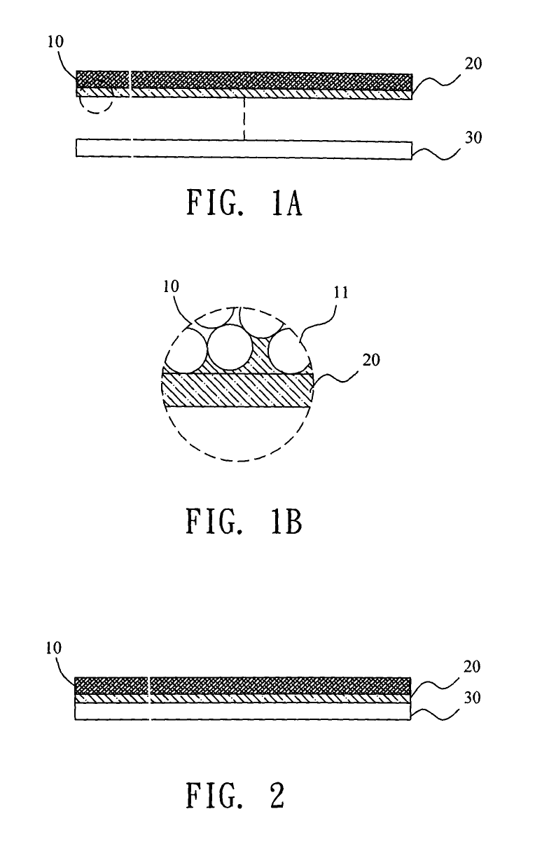

FIG. 2 is a schematic diagram showing part of the bamboo film structure in the embodiment of the invention. The bamboo film structure formed by the bamboo laminate sheet 10, the adhesive layer 20 and the film layer 30 forms a film structure, and therefore, the subsequent manufacturing modes are variable. For example, when utilizing for a case, there may have several methods to achieve. Please see the following embodiments.

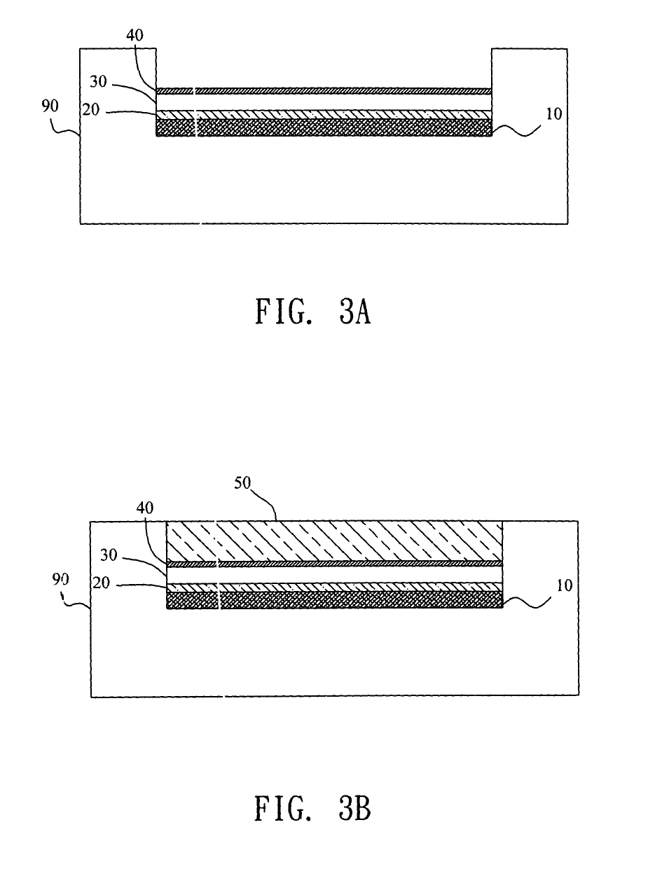

FIG. 3A and FIG. 3B are schematic diagram showing that the bamboo film structure is used in an in-mold decoration (IMD) technique to combine with a case.

The other side of the film layer 30 also may include an adhesive layer 40, and the bamboo film structure is disposed in a mould 90. A case 50 is formed in the mould 90 in the injecting molding process to make the case 50 combined with the bamboo laminate sheet 10 via the adhesive layer 40. Therefore, the bamboo laminate sheet 10 is easy to be combined with the case 50, which is shown in FIG. 3B. In another aspect, when the case 50 is manufactured by the injecting molding process, the film layer 30 is located between the bamboo laminate sheet 10 and the case 50 to prevent the bamboo laminate sheet 10 from being broken or scattered by injected melting slurry or scorched due to high temperature. Therefore, the film layer 30 needs to be a heat-resistant high polymer film such as a PET film. However, the thickness of the film layer 30 cannot be too large, and it may be smaller than 0.75 millimeter (mm). Otherwise, a temperature difference generated between the film layer 30 and the bamboo laminate sheet 10 is large, and the film layer 30 and the bamboo laminate sheet 10 may peel off from each other.

FIG. 4 is a schematic diagram showing that the bamboo film structure is used in another embodiment to combine with a case of the invention.

Since the bamboo film structure is a film, it has higher deforming ability than the conventional hardened bamboo laminate to allow the adhesive layer 40 directly attached to the case 50. However, the above-mentioned two manufacturing ways are just taken as examples. Other manufacturing methods to achieve the attachment are all included.

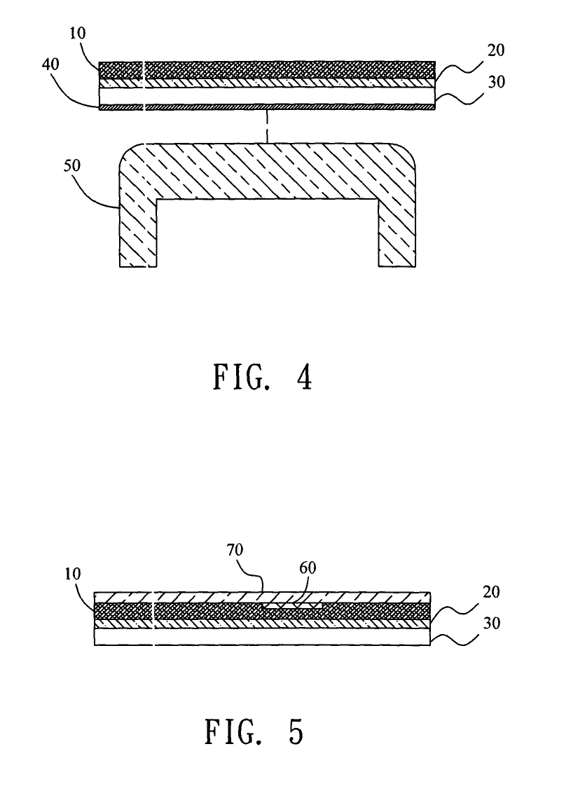

FIG. 5 is a schematic diagram showing an aspect of the bamboo film structure.

In another aspect, the surface of the bamboo laminate sheet 10 also may include special patterns 60 in a laser carving mode or other manufacturing modes. In addition, a protecting layer 70 also may be disposed above to protect the surface. The protecting layer 70 also may be polyurethane (PU) by baking coating or spraying painting.

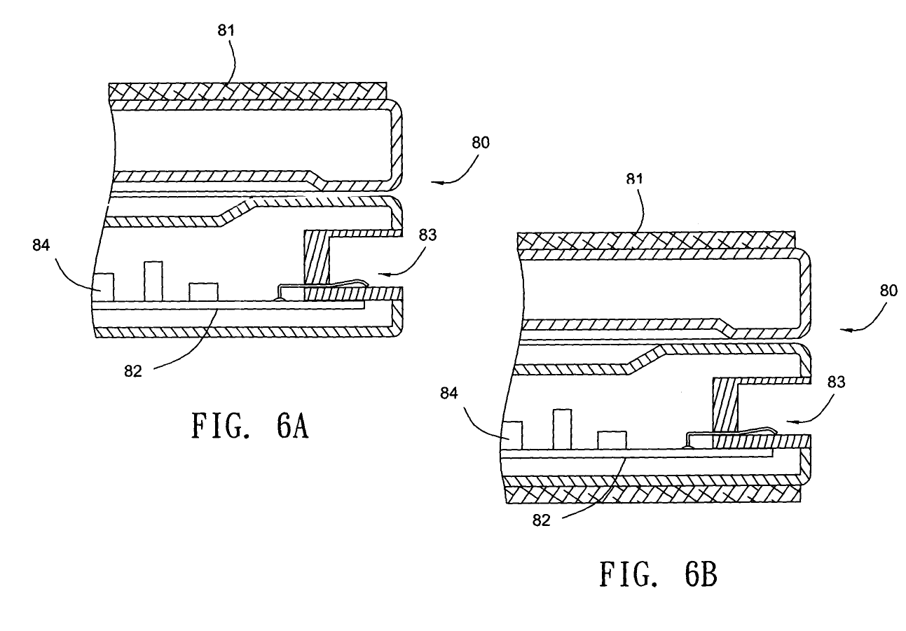

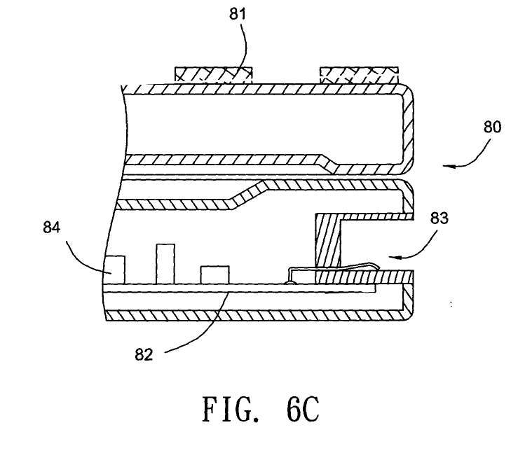

FIG. 6A is a schematic diagram showing that the bamboo film structure is used in another embodiment to combine with an electronic device of the invention.

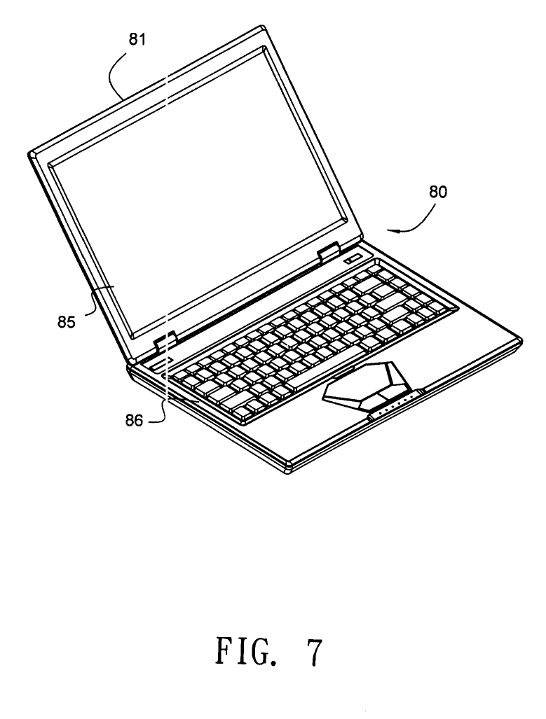

The electronic device structure includes an electronic device body 80, the case 50 and the bamboo film structure 81. The electronic device body 80 may include a printed circuit board (PCB) 82, a plurality of electric elements 84 and at least one connector 83 to perform specific functions, such as processing digital data, communicating, displaying and etc. Please see FIG. 7, take a laptop computer as example, the electronic device body 80 may further include a screen 85 and a plurality of inputting modules 86, such as keypads and pointer device.

The case 50 contains the electronic device body 80. As shown in FIG. 6A, the case 50 includes two portions which are pivotal connected together. For some apparatus, the case 50 may only have one portion, such as mobile phone, PDA, Tablet PC. The bamboo film structure 81 is attached to the case 50. As shown in FIG. 6A, the bamboo film structure 81 is attached on only top surface of the case 50. Please see FIG. 6B, the bamboo film structure 81 may be attached on both top and bottom surfaces of the case 50. Also, the bamboo film structure 81 may have special patterns 60 as mentioned in FIG. 5 or the bamboo film structure 81 is attached on part of the case 50 to form special patterns, characters or symbols, see FIG. 6C.

Therefore, in the bamboo film structure of the invention, unlike a furniture surface, the bamboo laminate sheet does not need to be baked and polished repeatedly, and it may be combined with the film layer directly via the adhesive layer made of glue to make the whole bamboo film structure to be a film. This facilitates the process of subsequent manufacture and the process of combining the bamboo film structure to the outer case of the electronic product. This not only saves the manufacturing processes and time cost, but also improves the yield to improve the possibility of mass production.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. A bamboo film structure comprising:
a bamboo laminate sheet;
an adhesive layer coated on one side of the bamboo laminate sheet; and
a film layer stuck to the bamboo laminate sheet by the adhesive layer.

2. The bamboo film structure according to claim 1, wherein the film layer is a Polyethylene Terephthalate (PET) film.

3. The bamboo film structure according to claim 1, wherein the adhesive layer comprises rubber solvent, petroleum ether, styrene-butadiene rubber and synthetic resin.

4. The bamboo film structure according to claim 3, wherein the rubber solvent is present in an amount of from about 5% to about 20% by weight of the total weight of the adhesive layer.

5. The bamboo film structure according to claim 3, wherein the petroleum ether is present in an amount of from about 8% to about 30% by weight of the total weight of the adhesive layer.

6. The bamboo film structure according to claim 3, wherein the styrene-butadiene rubber is present in an amount of from about 5% to 20% by weight of the total weight of the adhesive layer.

7. The bamboo film structure according to claim 3, wherein the synthetic resin is present in an amount of from about 15% to 30% by weight of the total weight of the adhesive layer.

8. The bamboo film structure according to claim 1, wherein another side of the bamboo laminate sheet further has a protecting layer.

9. A housing structure, comprising:
a case; and
a bamboo film structure, attached to the case, comprising:
a bamboo laminate sheet;
an adhesive layer coated on one side of the bamboo laminate sheet; and
a film layer stuck to the bamboo laminate sheet by the adhesive layer.

10. The housing structure according to claim 9, wherein the film layer is a Polyethylene Terephthalate (PET) film.

11. The housing structure according to claim 9, wherein the adhesive layer comprises rubber solvent, petroleum ether, styrene-butadiene rubber and synthetic resin.

12. The housing structure according to claim 11, wherein the rubber solvent is present in an amount of from about 5% to about 20% by weight of the total weight of the adhesive layer.

13. The housing structure according to claim 11, wherein the petroleum ether is present in an amount of from about 8% to about 30% by weight of the total weight of the adhesive layer.

14. The housing structure according to claim 11, wherein the styrene-butadiene rubber is present in an amount of from about 5% to 20% by weight of the total weight of the adhesive layer.

15. The housing structure according to claim 11, wherein the synthetic resin is present in an amount of from about 15% to 30% by weight of the total weight of the adhesive layer.

16. The housing structure according to claim 9, wherein another side of the bamboo laminate sheet further has a protecting layer.

17. The housing structure according to claim 9, wherein the bamboo film structure is attached to the case directly by an adhesive layer.

18. The housing structure according to claim 9, wherein the bamboo film structure is attached to the case by in-mold decoration (IMD) technique.

19. The housing structure according to claim 18, wherein the bamboo film structure further comprises an adhesive layer to combine the case in a mould.

20. The housing structure according to claim 18, wherein the film layer of the bamboo film structure has a thickness smaller than 0.75 millimeter.

21. An electronic device structure, comprising:
an electronic device body;
a case for containing the electronic device body; and
a bamboo film structure, attached to the case, comprising:
a bamboo laminate sheet;
an adhesive layer coated on one side of the bamboo laminate sheet; and
a film layer stuck to the bamboo laminate sheet by the adhesive layer.

22. The electronic device structure according to claim 21, wherein the film layer is a Polyethylene Terephthalate (PET) film.

23. The electronic device structure according to claim 21, wherein the adhesive layer comprises rubber solvent, petroleum ether, styrene-butadiene rubber and synthetic resin.

24. The electronic device structure according to claim 23, wherein the rubber solvent is present in an amount of from about 5% to about 20% by weight of the total weight of the adhesive layer.

25. The electronic device structure according to claim 23, wherein the petroleum ether is present in an amount of from about 8% to about 30% by weight of the total weight of the adhesive layer.

26. The electronic device structure according to claim 23, wherein the styrene-butadiene rubber is present in an amount of from about 5% to 20% by weight of the total weight of the adhesive layer.

27. The electronic device structure according to claim 23, wherein the synthetic resin is present in an amount of from about 15% to 30% by weight of the total weight of the adhesive layer.

28. The electronic device structure according to claim 21, wherein another side of the bamboo laminate sheet further has a protecting layer.

29. The electronic device structure according to claim 21, wherein the bamboo film structure is attached to the case directly by an adhesive layer.

30. The electronic device structure according to claim 21, wherein the bamboo film structure is attached to the case by in-mold decoration (IMD) technique.

31. The electronic device structure according to claim 30, wherein the bamboo film structure further comprises an adhesive layer to combine the case in a mould.

32. The electronic device structure according to claim 30, wherein the film layer of the bamboo film structure has a thickness smaller than 0.75 millimeter.

33. The electronic device structure according to claim 30, wherein the bamboo film structure is attached to part of the case.
